(19) United States
(12) Patent Application Publication
(10) Pub. No.: US 2006/0091384 A1
(43) Pub. Date: May 4, 2006

(54) Substrate testing apparatus with full contact configuration

(75) Inventors: Chung-Hsiung Ho, Kaohsiung (TW); Jui-Wen Wang, Yongkang City (TW); Tien-Ming Shih, Kaohsiung (TW); Kuang-Lin Lo, Kaohsiung County (TW)

Correspondence Address: BACON & THOMAS, PLLC, 625 SLATERS LANE, FOURTH FLOOR, ALEXANDRIA, VA, 22314, US

(73) Assignee: Advanced Semiconductor Engineering, Inc., Kaohsiung (TW)

(21) Appl. No.: 11/250,526

(22) Filed: Oct. 17, 2005

(30) Foreign Application Priority Data
Oct. 28, 2004 (TW) 93132782

(51) Int. Cl. H01L 23/58

(52) U.S. Cl. 257/48

(57) ABSTRACT

A substrate testing apparatus with full contact configuration. The apparatus includes a jig and a full-contact probe substrate. The jig has a conductive tape disposed thereon for fully electrically connecting a plurality of first connecting pads disposed on an upper surface of a substrate strip. The full-contact probe substrate has a contact surface and includes a plurality of conductive bumps and contact pads. The conductive bumps are disposed on the contact surface, and are used for individually probing a plurality of corresponding second connecting pads disposed on a lower surface of the substrate strip. The contact pads are electrically connected to the conductive bumps. The substrate strip is fully tested by means of the jig and the full-contact probe substrate.

This application claims the benefit of Taiwan application Serial No. 93132782, filed Oct. 28, 2004, the subject matter of which is incorporated herein by reference.

### BACKGROUND OF THE INVENTION

1. Field of the Invention

The invention relates in general to an electricity testing apparatus capable of electrically connecting two sides of a substrate strip, and more particularly to a substrate testing apparatus with full contact configuration.

2. Description of the Related Art

The electric qualities of conventional substrate strip applicable to BGA package can only be assured after being tested by the substrate testing apparatus 10 shown in FIG. 1. Referring to both FIG. 1 and FIG. 2, conventional substrate strip 200 has an upper surface 210 and a lower surface 220. The upper surface 210 has a plurality of first connecting pads 230 disposed thereon. The lower surface 220 has a plurality of second connecting pads 240 disposed thereon. The substrate strip 200 has a plurality of molding regions 211 defined thereon. Each of the molding regions 211 includes a plurality of substrate units 212 arranged in matrix as shown in FIG. 2. The first connecting pads 230 are formed within the molding regions 211 and are electrically connected to the corresponding second connecting pads 240. Referring to FIG. 1, the substrate testing apparatus 10 includes an upper jig 11 and a lower dial 12. The upper jig 11 has a conductive glue 11a disposed thereon, and the lower dial 12 has a plurality of probes 12a disposed thereon. The probes 12a are used for individually probing the corresponding second connecting pad 240 to be fully electrically connected to the first connecting pads 230 in corporation with the upper jig 11 and the conductive glue 11a to test the electrical functions of the substrate strip 200. However, currently the substrate testing apparatus 10 can only test one molding regions 211 at a time. When the substrate strip 200 has a plurality of molding regions 211, the testing needs to be divided into several stages, which is very time-consuming. Besides, along with the development of the high density semiconductor package with several ends, the pitch of the second connecting pads 240 will become smaller. Therefore the probes 12a disposed on the lower dial 12 would have to leave part of the second connecting pad 240 and would not be able to probe all of the corresponding second connecting pads 240, causing the second connecting pads 240 to be exposed to the risk of open-loop or short-circuit.

A testing apparatus disclosed in Taiwanese Publication No. 438053 “Testing Apparatus for BGA Substrate” includes a vacuuming apparatus, a testing circuit board and a conductive rubber. The testing circuit board is disposed on the vacuum apparatus. The testing circuit board has a plurality of holes. The testing apparatus sucks the conductive rubber by the vacuuming apparatus through the holes of the testing circuit board, so that the conductive rubber disposed on the testing circuit board can be electrically connected to the testing circuit board and a BGA substrate. The testing apparatus only discloses how one surface of the BGA substrate is electrically connected to a testing apparatus but does not disclose how the other surface of the BGA substrate is electrically connected to the testing apparatus. Conventionally, a plurality of probes are used to contact a plurality of connecting pads of the BGA substrate, and then the probes are electrically connected to the testing apparatus. However, as the number of connecting pads (I/O) of the BGA substrate becomes larger and larger, the pitch becomes smaller and smaller, thus the probes can no longer individually contact the connecting pads in corporation with the connecting pads of the BGA substrate to be tested.

### SUMMARY OF THE INVENTION

It is therefore an object of the invention to provide a substrate testing apparatus with full contact configuration. The apparatus includes a jig and a full-contact probe substrate. A contact surface of the full-contact probe substrate has a plurality of conductive bumps disposed thereon. A plurality of contact pads can be formed on at least one lateral side of the full-contact probe substrate to be electrically connected to the conductive bumps. The full-contact probe substrate can replace a conventional lower dial whose probe pitch can not be miniaturized, so that a lower surface of the substrate strip is fully contacted when the substrate strip is electrically tested. That is, the conductive bumps of the full-contact probe substrate can individually probe a plurality of connecting pads disposed on the substrate strip and electrically test the substrate strip when incorporated with the jig which is disposed over the substrate strip and fully electrically connected.

It is a further object of the invention to provide a substrate testing apparatus with full contact configuration. A substrate strip to be tested has an upper surface on which a plurality of molding regions are defined. The substrate testing apparatus uses a plurality of conductive tapes disposed on a jig to electrically connect a plurality of connecting pads disposed on each of the molding regions, so that the upper surface of the substrate strip is fully contacted at a time.

The substrate testing apparatus with full contact configuration according to the invention is for electrically testing a substrate strip. The substrate strip has an upper surface and a lower surface. The substrate strip includes a plurality of first connecting pads and second connecting pads. The first connecting pads are formed on the upper surface, the second connecting pads are formed on the lower surface, and the substrate testing apparatus is used for testing the electrical connection path between the first connecting pads and the corresponding second connecting pad. The substrate testing apparatus includes a jig and a full-contact probe substrate. The jig is for fully electrically connecting the first connecting pads of the substrate strip. The full-contact probe substrate has a contact surface, and includes a plurality of contact pads and conductive bumps. The conductive bumps are disposed on the contact surface, and are used for individually probing each of the corresponding second connecting pads disposed on the substrate strip. The contact pads can be formed on at least one lateral side of the full-contact probe substrate to be electrically connected to the conductive bumps.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1 (Prior Art) is a cross-sectional view of a conventional substrate testing apparatus for electrically testing a substrate strip;

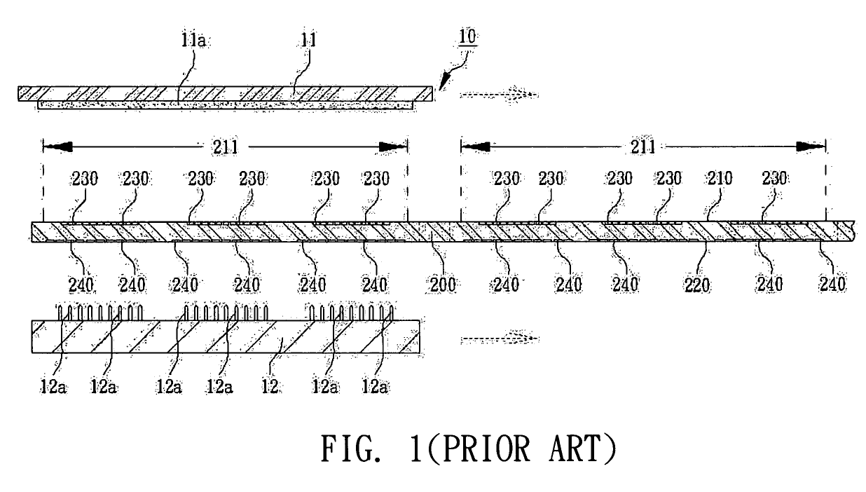

FIG. 2 (Prior Art) is a diagram of a lower surface of a conventional substrate strip to be tested;

FIG. 3 is a cross-sectional view of a substrate testing apparatus with full contact configuration for electrically testing a substrate strip according to a preferred embodiment of the invention; and

FIG. 4 is a diagram of a contact surface of the full-contact probe substrate according to a preferred embodiment of the invention.

### DETAILED DESCRIPTION OF THE INVENTION

Referring to the accompanied drawings, the invention is exemplified by an embodiment disclosed below.

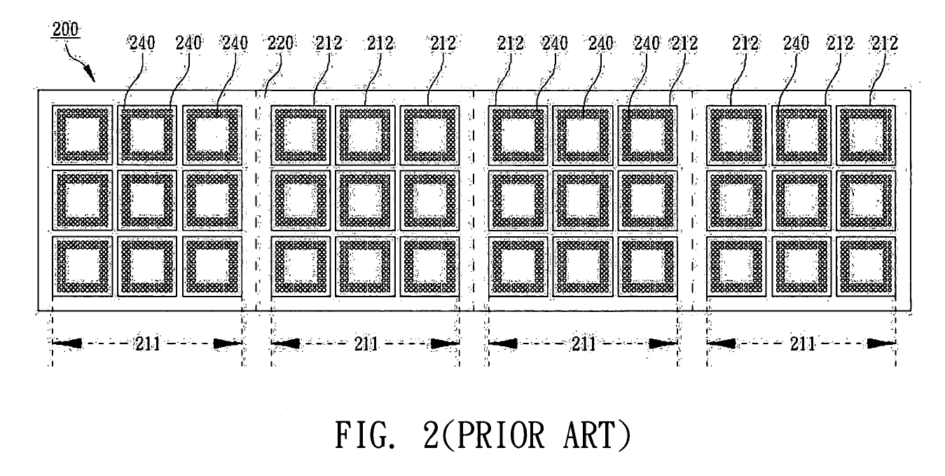

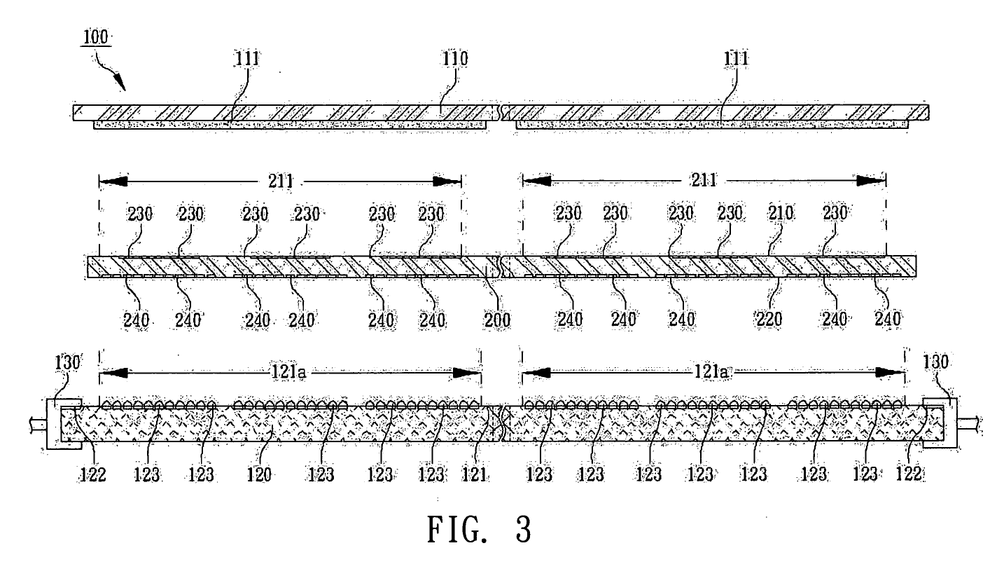

Referring to FIG. 3, a substrate testing apparatus with full contact configuration 100 for electrically testing a substrate strip 200 according to a preferred embodiment of the invention is shown. The substrate strip 200 has an upper surface 210 and a lower surface 220. The substrate strip 200 includes a plurality of first connecting pads 230 disposed on the upper surface 210 and a plurality of second connecting pads 240 disposed on the lower surface 220. In the present embodiment, the pitch of the first connecting pads 230 is smaller than the pitch of the second connecting pads 240. Referring to FIG. 2, the upper surface 210 of the substrate strip 200 has a plurality of molding regions 211 defined thereon, each of the molding regions 211 includes a plurality of substrate units arranged in matrix 212. The first connecting pads 230 are formed within the molding regions 211.

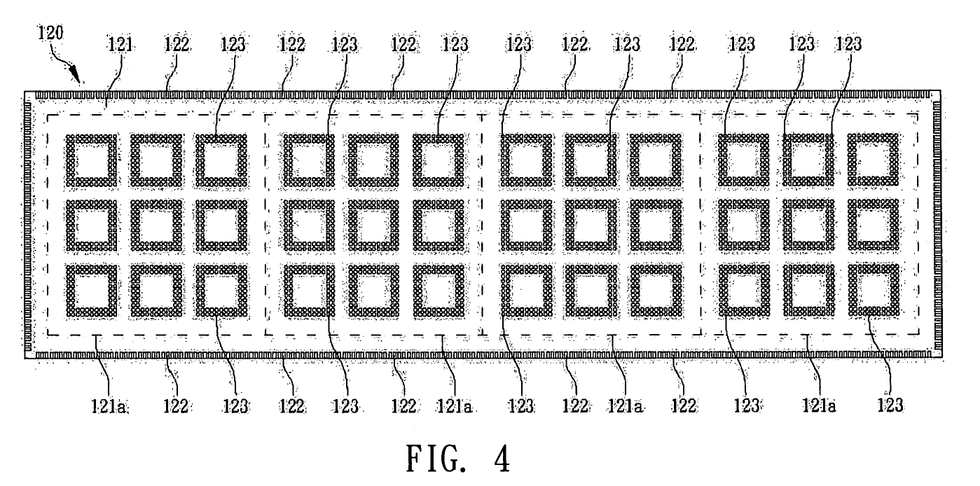

Referring to FIG. 3 and FIG. 4, the substrate testing apparatus 100 can be used for testing whether the electrical connection path between the first connecting pads 230 of the substrate strip 200 and the corresponding second connecting pads 240 is open-looped or short-circuited. The substrate testing apparatus 100 includes a jig 110 and a full-contact probe substrate 120. The jig 110 has a plurality of conductive tapes 111 disposed thereon. In the present embodiment, the number of the conductive tapes 111 corresponds to the number of the molding regions 211 on the substrate strip 200 for electrically connecting the first connecting pads 230 disposed on each molding regions 211 of the substrate strip 200. The full-contact probe substrate 120 can be a multi-layered printed circuit board having two or four layers with the thickness of 0.5 to 1 mm. The full-contact probe substrate 120 has a contact surface 121 and includes a plurality of contact pads 122 and conductive bumps 123. The contact pads 122 are electrically connected to the conductive bumps 123 disposed on the contact surface 121. As shown in FIG. 4, in the present embodiment, the contact surface 121 has a plurality of testing regions 121a defined thereon. The number of the testing regions 121a corresponds to the number of the molding regions 211 disposed on the substrate strip 200. The conductive bumps 123, whose height ranges from 50 to 100 μm, faces towards the jig 110 to be corresponding to all of the second connecting pads 211 disposed on the substrate strip 200, so that the conductive bumps 123 of each testing region 121a can individually probe each of the corresponding second connecting pads 240 disposed on the molding regions 211 of the substrate strip 200 during testing. In the present embodiment, the contact pads 122 are formed on a lateral side of the full-contact probe substrate 120, or, the contact pads 122 can be connected to a FPC connector 130 for electrically transmitting the test signals to a testing apparatus (not shown in the diagram).

In addition to using the conductive bumps 123 of the full-contact probe substrate 120 to individually probe the corresponding second connecting pad 240, the invention further uses the conductive tapes 111 of the jig 110 to fully contact the first connecting pads 230 of the substrate strip 200 at one time without moving the substrate strip 200 at all. Therefore, the substrate testing apparatus with full contact configuration 100 can fully contact the first connecting pads 230 disposed on the upper surface 210 of the substrate strip to be tested 200 as well as the second connecting pads 240 disposed on the lower surface 220 at one time, so as to test whether the electrical connection path between the first connecting pads 230 of the substrate strip 200 and the corresponding second connecting pads 240 is open-looped or short-circuited. Compared with the design of a conventional lower dial which is equipped with a probe, the design of the full-contact probe substrate 120 according to the invention corresponds to the conductive bumps 123 disposed on all of the second connecting pads 240 of the substrate strip 200. Besides, the contact pads 122 of the full-contact probe substrate 120 enable the FPC connector 130 to be electrically connected, increasing the circuiting region of the full-contact probe substrate 120 (not shown in the diagram).

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A substrate testing apparatus with full contact configuration for electrically testing a substrate strip, wherein the substrate strip has an upper surface and a lower surface, the substrate strip comprises a plurality of first connecting pads disposed on the upper surface and a plurality of second connecting pads disposed on the lower surface, and the substrate testing apparatus comprises:
a jig used for fully electrically connecting the first connecting pads of the substrate strip; and
a full-contact probe substrate having a contact surface and comprising:
a plurality of contact pads and a plurality of conductive bumps, wherein the conductive bumps are disposed on the contact surface, each conductive bump is used for individually probing each second connecting pad of the substrate strip, and the contact pads are electrically connected to the conductive bumps.

2. The substrate testing apparatus with full contact configuration according to claim 1, wherein the jig has at least a conductive tape disposed thereon for electrically connecting the first connecting pads of the substrate strip.

3. The substrate testing apparatus with full contact configuration according to claim 1, wherein the upper surface of the substrate strip has a plurality of molding regions defined thereon, and the first connecting pads are formed within the molding regions.

4. The substrate testing apparatus with full contact configuration according to claim 3, wherein each of the molding regions comprises a plurality of substrate units arranged in matrix.

5. The substrate testing apparatus with full contact configuration according to claim 3, wherein the contact surface of the full-contact probe substrate has a plurality of testing regions defined thereon, and the number of the testing regions corresponds to the number of the molding regions disposed on the substrate strip.

6. The substrate testing apparatus with full contact configuration according to claim 1, wherein the full-contact probe substrate is a multi-layered printed circuit board.

7. The substrate testing apparatus with full contact configuration according to claim 1, wherein a pitch of the first connecting pads of the substrate strip is smaller than a pitch of the second connecting pads.

8. The substrate testing apparatus with full contact configuration according to claim 1, wherein the contact pads of the full-contact probe substrate are formed on at least one lateral side of the full-contact probe substrate.

9. The substrate testing apparatus with full contact configuration according to claim 1, further comprising a connector for electrically connecting the contact pads.
